(19) United States
(12) Patent Application Publication
(10) Pub. No.: US 2008/0310118 A1
(43) Pub. Date: Dec. 18, 2008

(54) CPU Heat Sink Mounting Method And Apparatus

(75) Inventors: Brandon Joel Brocklesby, Pflugerville, TX (US); Juan Manuel Gonzalez, Round Rock, TX (US); Laurent Andrew Regimbal, Round Rock, TX (US)

Correspondence Address: BAKER BOTTS, LLP, 910 LOUISIANA, HOUSTON, TX, 77002-4995, US

(73) Assignee: DELL PRODUCTS L.P., Round Rock, TX (US)

(21) Appl. No.: 11/764,424

(22) Filed: Jun. 18, 2007

(51) Int. Cl. H05K 7/20

(52) U.S. Cl. 361/719

(57) ABSTRACT

A system and method for mounting a heat sink associated with an electronics component are disclosed. The disclosure provides a method including connecting a CPU support bracket to a board using one or more support bracket connectors, mounting a CPU to the CPU support bracket, and mounting a heat sink assembly to the CPU support bracket using one or more heat sink connectors configured to mate with the one or more support bracket connectors.

The disclosure also provides a method for mounting a heat sink assembly associated with a CPU, including removing one or more socket screws installed at one or more corners of a socket disposed in a board, installing one or more support bracket connectors configured to mate with respective holes in the board, and mounting a heat sink assembly to the support bracket connectors using one or more heat sink connectors configured to mate with the one or more support bracket connectors.

The disclosure also provides a system for mounting an electronic component and associated heat sink to a board, including a support bracket operable to retain an electronic component and provide at least one electrical connection between a board and the electronic component, a support bracket connector configured to releasably connect the support bracket to the board, and a heat sink connector configured to releasably connect a heat sink with the support bracket connector.

### TECHNICAL FIELD

The present disclosure relates in general to the manufacture of information handling systems, and more particularly to a system and method for mounting a heat sink.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

An information handling system may include one or more microprocessors or other electronic components configured to perform the functions of a central processing unit (CPU). One or more heat sinks may be associated with an electronic component to increase the effective thermal mass and heat dissipation associated with the component. Electronics designers and users may find that a better cooling rate allows increased operating speeds of the components so cooled. Some benefits of increased operating speeds may include, for example, an increase in how quickly and/or efficiently information may be processed, stored, and/or communicated.

At the same time, an increase in the number of components associated with a CPU or other electronics component presents potential increases in cost, manufacturing complexity, failure modes and/or additional negative consequences. Designers, manufacturers, purchasers and users of information handling systems, CPUs, integrated circuits, microprocessors, and/or any other electronics components may be well served by techniques and apparatus that provide increased performance without the typically attendant negative consequences.

A traditional method for mounting a processor or other electronic component to a circuit board includes placing the component into a socket designed to accept the component and provide the appropriate electrical leads to the component. The circuit board is imprinted with or otherwise comprises circuitry configured to facilitate the operation of the component. In addition, the circuit board may include additional holes configured to facilitate the mounting of a heat sink associated with the component. Such holes may often be located external to the component socket.

As the design of electronic products, such as information handling systems, and their attendant circuit boards evolves, the products often become smaller. The products are often required to provide equivalent functionality in a smaller space than provided for earlier designs. The miniaturization of these parts and products presents challenges in circuit design (for minimum volume) and heat dissipation for circuits and components packed into a smaller space. In some such cases, the requirement of additional holes external to the component socket inhibits design options by consuming critical space on the circuit board. A method or system eliminating the need for such holes would, among other benefits, may provide additional space for, among other components, critical trace routing and additional components.

### SUMMARY

In accordance with the teachings of the present disclosure, various disadvantages and problems associated with mounting a heat sink in association with an electronic component may be reduced or eliminated. In one particular embodiment, custom hardware may be used in place of standard socket screws to eliminate a portion (e.g., up to half) of the holes required in the circuit board, provide an increased amount of continuous surface of the circuit board, and/or allow the heat sink to be positioned closer to the relevant electronic component.

In accordance with one embodiment of the present disclosure, a method for mounting a heat sink in association with an electronic component is provided. The method may include connecting the component to a support bracket using one or more support bracket connectors and mounting a heat sink assembly using one or more heat sink connectors configured to mate with the one or more support bracket connectors.

In accordance with another embodiment of the present disclosure, a method for mounting a heat sink in association with a CPU is provided. The method may include removing one or more socket screws, installing one or more support bracket connectors and mounting a heat sink assembly using or more heat sink connectors configured to mate with the one or more support bracket connectors.

In accordance with yet another embodiment of the present disclosure, a system for mounting an electronic component and a heat sink to a circuit board is provided. The system may include a support bracket, a support bracket connector and a heat sink connector configured to releasably connect the heat sink with the support bracket connector.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a flow chart for an example method for mounting a heat sink associated with a CPU to a board in accordance with teachings of the present disclosure;

FIG. 2 illustrates a flow chart for another example method for mounting a heat sink associated with a CPU to a board in accordance with teachings of the present disclosure;

FIG. 3 illustrates a system for mounting an electronic component to a circuit board in accordance with teachings of the present disclosure;

FIG. 4 illustrates a system for mounting an electronic component and associated heat sink to a circuit board in accordance with teachings of the present disclosure; and

FIGS. 5A and 5B illustrate embodiments of connectors that may be used in accordance with teachings of the present disclosure.

### DETAILED DESCRIPTION

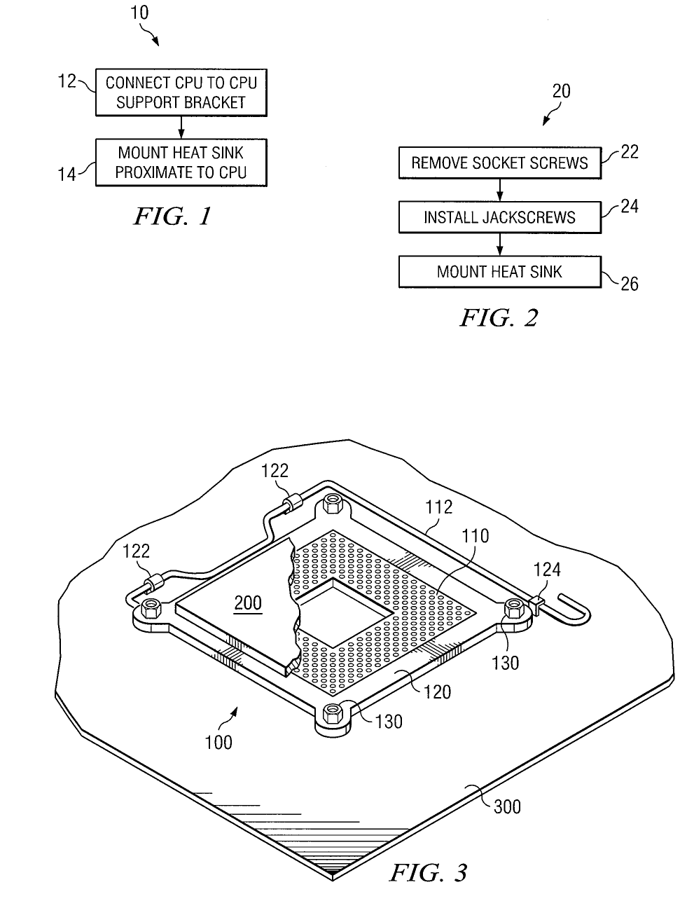

Preferred embodiments and their advantages are best understood by reference to FIGS. 1 through 5B, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components or the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

FIG. 1 illustrates a flow chart of an example method 10 for mounting a heat sink associated with an electronic component (e.g., a CPU) to a circuit board in accordance with teachings of the present disclosure. Although the following discussion focuses on systems and methods for providing a heat sink for a CPU, it should be understood that the disclosed systems and methods may be similarly applied for providing heat sinks for any other types of electronic components (e.g., amplifiers, and/or any other heat generating component). Although the following discussion focuses on systems or methods in light of a user, it should be understood that the disclosed systems and methods may be similarly applied by an automated device or system.

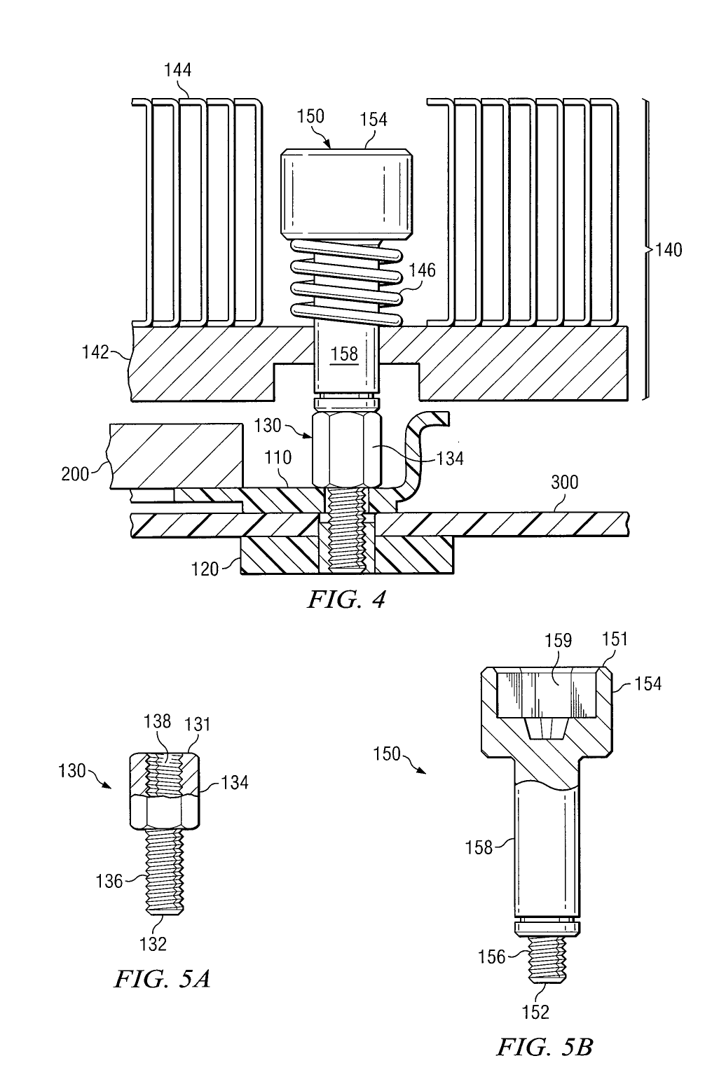

Method 10 may include steps appropriate for mounting a CPU and a heat sink assembly in association with a pre-existing CPU support bracket or may be part of a larger method including installation of a CPU support bracket. Method 10 is now discussed in greater detail with respect to FIGS. 3 and 4.

At step 12, a user may connect a CPU 200 to a CPU support bracket 120. CPU support bracket 120 may be associated with a board 300 (e.g., a printed circuit board and/or another board) suitable for use with CPU support bracket 120. Connecting CPU 200 to CPU support bracket 120 may include using any device or component configured to provide an electronic connection between CPU 200 and the circuitry present on board 300 as well as a physical connection between CPU 200 and board 300. For example, CPU 200 may be mounted in a CPU socket and/or CPU slot.

In some embodiments, step 12 may include operating a lever or other component to provide a releasable physical connection as desired. Such a feature may allow for “zero insertion force” operation. In some embodiments, step 12 may include engaging a set of electronic connectors to connect the circuitry within CPU 200 to the circuitry present on board 300. For example, step 12 may include engaging a ball grid array. In some embodiments, step 12 may include engaging a fine ball grid array, a plastic ball grid array, a land grid array, a pin grid array, a dual in-line surface mount, and/or any other method of providing electrical connections between circuitry of board 300 and circuitry of CPU 200.

At step 14, a user may mount a heat sink assembly 140 proximate to CPU 200. As shown in FIG. 4, mounting heat sink assembly 140 may include physically connecting heat sink assembly 140 to one or more support bracket connectors 130 used to mount CPU support bracket 120 to board 300. In some embodiments, step 14 may include engaging threads in one or more heat sink connectors 150 to threads associated with support bracket connectors 130.

FIG. 2 illustrates a flow chart of another example method 20 for mounting a heat sink associated with an electronic component (e.g., a CPU) to a board in accordance with teachings of the present disclosure. Again, although the following discussion focuses on systems and methods for providing a heat sink for a CPU, it should be understood that the disclosed systems and methods may be similarly applied for providing heat sinks for any other types of electronic components (e.g., amplifiers, and/or any other heat generating component). Although the following discussion focuses on systems or methods in light of a user, it should be understood that the disclosed systems and methods may be similarly applied by an automated device or system.

Method 20 may include steps appropriate for mounting a CPU and a heat sink assembly in association with a pre-existing CPU support bracket or may be part of a larger method including installation of a CPU support bracket. Method 20 is herein discussed in relation to FIGS. 3 and 4.

At step 22, a user may remove one or more socket screws associated with CPU support bracket 120. Step 22 may include removing socket screws provided with CPU support bracket 120 or used to connect CPU support bracket 120 to board 300.

At step 24, a user may install support bracket connectors 130 to connect CPU support bracket 120 to board 300. In some embodiments, step 24 may include installation of support bracket connectors 130 including threads for mounting additional connectors thereon.

At step 26, a user may mount heat sink assembly 140. Mounting heat sink assembly 140 may include installing heat sink connectors 150 using threads 156 disposed thereon. Threads 156 may be configured to connect with internal threads 138 associated with support bracket connectors 130.

FIG. 3 illustrates an apparatus with some parts broken away for mounting an electronic component to a circuit board in accordance with teachings of the present disclosure. In embodiments such as that depicted in FIG. 3, system 100 may include a socket 110, a support bracket 120, and support bracket connectors 130. System 100 may include any apparatus operable to physically couple CPU 200 to board 300. Although the following discussion focuses on systems and methods for providing a heat sink for a CPU, it should be understood that the disclosed systems and methods may be similarly applied for providing heat sinks for any other types of electronic components (e.g., amplifiers, and/or any other heat generating component).

Socket 110 may include any device or component configured to provide an electrical connection between CPU 200 and the circuitry present on board 300, as well as a physical connection between CPU 200 and board 300. For example, socket 110 may include a CPU socket and/or CPU slot.

In some embodiments, socket 110 may include a lever 112 or other component operable to provide a releasable physical connection as desired. Such a feature may allow for “zero insertion force” operation. For example, socket 110 may include a known “socket 478”, “socket T”, or any of the many CPU sockets provided to interface with one or more available CPUs.

In some embodiments, socket 110 may include a set of electrical connectors operable to connect circuitry of CPU 200 to the circuitry of board 300. For example, socket 110 may include a ball grid array. In some embodiments, socket 110 may include a fine ball grid array, a plastic ball grid array, a land grid array, a pin grid array, a dual in-line surface mount, and/or any other method of providing electrical connections between circuitry of board 300 and circuitry of CPU 200.

Support bracket 120 may include any device or component generally configured to provide an interface between CPU 200 and board 300. Support bracket 120 may include socket 110 and/or a physical bracket configured to support socket 110 and CPU 200. In some embodiments, socket 110 may be integral to support bracket 120. For example, in the embodiment depicted in FIG. 3, support bracket 120 may include features or components configured to accept support bracket connectors 130 so that support bracket 120 may be attached to board 300.

Support bracket 120 may include additional features configured to facilitate installation of socket 110 and/or CPU 200. For example, as shown in FIG. 3, support bracket may include one or more pivot mounts 122 and a stop 124. Pivot mounts 122 may include any feature or component configured to allow rotation of lever 112. Stop 124 may include any feature or component configured to restrict undesired movement of lever 112 (e.g., using a releasable detent).

FIG. 4 illustrates a system for mounting an electronic component and a heat sink to a circuit board in accordance with teachings of the present disclosure. In embodiments such as that depicted in FIG. 4, system 100 may include socket 110, CPU support bracket 120, support bracket connectors 130, heat sink assembly 140 and heat sink connector 150. Although FIG. 4 shows a single support bracket connector 130 and heat sink connector 150, a full system may include any appropriate number of each. For example, a system may include four support bracket connectors 130 and four heat sink connectors 150—one of each to be installed as depicted in FIG. 4 at each corner of CPU support bracket 120 or socket 110.

Such embodiments may allow mounting CPU 200 to board 300 with one or more advantages when compared to previous techniques. For example, some embodiments of the present disclosure may allow: design of board 300 with fewer mounting holes; increased contiguous area for routing of circuits; reduced interference between heat sink assembly 140 and adjacent components; and/or reduced total height of heat sink assembly 140 and CPU 200.

Support bracket connectors 130 may include any device or component configured to provide a releasable connection between CPU support bracket 120 and board 300. As shown in FIG. 4, support bracket connectors 130 may include threaded connectors configured to pass through straight holes in board 300 and connect to threaded holes in CPU support bracket 120.

Heat sink assembly 140 may include any device or component configured to increase the thermal mass of associated electronic component or CPU 200. For example, in embodiments such as that shown in FIG. 4, heat sink assembly 140 may include a heat sink 142, one or more fins 144, one or more springs 146, and one or more heat sink connectors 150.

Heat sink 142 may be formed from any appropriate material or component configured to increase heat transfer away from CPU 200. For example, heat sink 142, when associated with CPU 200, may serve to increase the effective thermal mass and heat dissipation associated with CPU 200. Heat sink 142 may include a mass with relatively high thermal conductivity (e.g., a metal block or aluminum and/or copper alloy). Heat sink 142 may be fabricated and/or shaped in any manner to facilitate heat transfer between CPU 200 and heat sink 142 and/or to facilitate mounting heat sink 142 to associated hardware in heat sink assembly 140.

Fins 144 may include any component or feature of heat sink assembly 140 configured to increase heat transfer from heat sink 142 to the environment. Fins 144 may serve to increase the surface area of heat sink assembly 140 and, therefore, increase the rate of heat transfer through convection, conduction, and/or radiation between heat sink 142 and the environment. Although the embodiment shown in FIG. 4 includes long, thin fins, fins 144 may include any physical features or characteristics that tend to increase the surface area-to-volume ratio of heat sink assembly 140. Like heat sink 142, fins 144 may also be made of any material with relatively high thermal conductivity (e.g., aluminum and/or copper alloy).

Springs 146 may include any feature or component generally configured to compress heat sink assembly 140 and/or move heat sink assembly 140 toward CPU 200 to be cooled. For example, springs 146 may include a helical spring configured to be compressed by the installation of heat sink connectors 150 in association with heat sink assembly 140. Including springs 146 may be preferable to connecting heat sink assembly 140 to CPU support bracket 120 with the compression applied by heat sink connector 150 to heat sink assembly 140. In particular, springs 146 may allow some movement or release of pressure in the event the dimensions of CPU 200, CPU support bracket 120, and/or heat sink assembly 140 may not match exact design specifications.

Heat sink connectors 150 may include any component or device configured to releasably connect heat sink assembly 140 to CPU support bracket 120. For example, heat sink connectors 150 may include screws configured to mount into threaded holes provided by support bracket connectors 130. In other embodiments, heat sink connectors 150 may include other features configured to mate with complementary features on CPU support bracket 120 and/or support bracket connectors 130.

FIG. 5A is a schematic drawing with parts broken away showing one embodiment of support bracket connector 130 for use in accordance with teachings of the present disclosure. In embodiments such as that shown in FIG. 5A, support bracket connector 130 may include a top 131, a bottom 132, and a head 134. Support bracket connector 130 may include any device or component generally configured to connect CPU support bracket 120 and/or socket 110 to board 300.

Top 131 may include any feature or component of support bracket connector 130 which may be exposed after support bracket connector 130 is installed. For example, top 131 may include a flat face of support bracket connector 130. In some embodiments, top 131 may include a socket or internal threads 138 configured to releasably mate with suitable features disposed on heat sink connectors 150.

Bottom 132 may include any feature or component of support bracket connector 130 at the opposite end of support bracket connector 130 from top 131. Bottom 132 may be disposed within CPU support bracket 120 or board 300 during installation of support bracket connector 130. Bottom 132 may include any feature or component configured to releasably mate with suitable features disposed in or on board 300 or CPU support bracket 120. For example, bottom 132 may include a threaded portion 136 configured to mate with threads disposed in board 300.

Head 134 may include any feature or component of support bracket connector 130 configured to compress components to be joined. For example, as shown in FIG. 4, head 134 provides compression to socket 110, CPU support bracket 120, and board 300 once installed. Head 134 may include an extended portion of support bracket connector 130 or any other feature configured to be turned by a wrench, driver and/or other tool.

FIG. 5B is a schematic drawing with parts broken away showing one embodiment of heat sink connector 150 for use in accordance with teachings of the present disclosure. In embodiments such as that shown in FIG. 5B, heat sink connector 150 may include a top 151, a bottom 152, a head 154, and a barrel 158.

Top 151 may include any feature or component of support bracket connector 130 which may be exposed after heat sink connector 150 is installed. For example, top 151 may include a flat face of heat sink connector 150. In some embodiments, top 151 may include a socket 159 configured to releasably mate with suitable tools such as drivers, wrenches, and/or other tools.

Bottom 152 may include any feature or component of heat sink connector 150 at the opposite end of heat sink connector 150 from top 151. Bottom 152 may be disposed in or on support bracket connector 130 during installation of heat sink assembly 140. Bottom 152 may include any feature or component configured to releasably mate with suitable features disposed within support bracket connector 130. For example, bottom 152 may include a threaded portion 156 configured to mate with threads 138 disposed in head 134 of support bracket connector 130.

Head 154 may include any feature or component of heat sink connector 150 configured to compress spring 146 when installed in accordance with FIG. 4. Head 134 may include an extended portion of support bracket connector 130 or any other feature configured to be turned by a wrench, driver, and/or other tool.

Barrel 158 may include any feature or component of heat sink connector 150 configured to mate with appropriate features disposed in or on heat sink assembly 140. For example, as shown in FIG. 4, barrel 158 may include a cylinder sized to fit within a round hole in heat sink assembly 140. Barrel 158 may have any dimensions appropriate for such mounting.

Although the figures and embodiments disclosed herein have been described with respect to processors and information handling systems, it should be understood that various changes, substitutions and alternations can be made herein without departing from the spirit and scope of the disclosure as illustrated by the following claims. For instance, the teachings of the present disclosure may be applied to other electronics components such as amplifiers and may be applied to other systems such as consumer kitchen appliances, stereos, and/or any system incorporating high performance electronics components.

What is claimed is:

1. A method for mounting a heat sink associated with a CPU to a board, the method comprising:
connecting a CPU support bracket to a board using one or more support bracket connectors;
mounting a CPU to the CPU support bracket; and
mounting a heat sink assembly to the CPU support bracket using one or more heat sink connectors configured to mate with the one or more support bracket connectors, the heat sink assembly configured to remove heat from the CPU.

2. The method of claim 1 wherein the one or more support bracket connectors comprise jackscrews.

3. The method of claim 1 wherein connecting the CPU support bracket to the board includes using four support bracket connectors.

4. The method of claim 1 wherein mounting the heat sink assembly to the CPU support bracket includes fastening the one or more heat sink connectors into threads formed in the top of the one or more support bracket connectors.

5. The method of claim 1 wherein mounting the heat sink assembly to the CPU support bracket includes placing a spring to apply tension to the one or more heat sink connectors.

6. The method of claim 1 wherein connecting the CPU support bracket to the board includes applying cement to threads disposed on the one or more support bracket connectors.

7. A method for mounting a heat sink assembly associated with a CPU, the method comprising:
removing one or more socket screws installed at one or more corners of a socket disposed in a board;
installing one or more support bracket connectors configured to mate with respective holes in the board; and
mounting a heat sink assembly to the support bracket connectors using one or more heat sink connectors configured to mate with the one or more support bracket connectors.

8. The method of claim 7 wherein:
removing one or more socket screws includes removing four socket screws; and
installing one or more support bracket connectors includes installing four support bracket connectors.

9. The method of claim 7 wherein mounting the heat sink assembly includes fastening the one or more heat sink connectors into threads formed in the top of the one or more support bracket connectors.

10. The method of claim 7 wherein mounting the heat sink assembly includes placing a spring between the heat sink assembly and a head of one of the heat sink connectors.

11. The method of claim 7 wherein the one or more support bracket connectors comprise jackscrews.

12. A method for mounting an electronic component to a board, the method comprising:
connecting a support bracket to a board using one or more support bracket connectors;
mounting an electronic component to the support bracket; and
mounting a heat sink assembly associated with the electronic component using one or more heat sink connectors configured to mate with the one or more support bracket connectors.

13. A system for mounting an electronic component and associated heat sink to a board, the system comprising:
a support bracket operable to retain an electronic component and provide at least one electrical connection between a board and the electronic component;
a support bracket connector configured to releasably connect the support bracket to the board; and
a heat sink connector configured to releasably connect a heat sink with the support bracket connector.

14. The system of claim 13 wherein the heat sink connector comprises a screw.

15. The system of claim 13 wherein the support bracket connector comprises a jackscrew.

16. The system of claim 13 wherein the support bracket connector includes:
an external thread configured to mate with a thread associated with the support bracket; and
an internal thread configured to mate with a thread associated with the heat sink connector.

17. The system of claim 13 further comprising four support bracket connectors.

18. The system of claim 13 further comprising the support bracket connectors configured to provide solder ball joint relief for the at least one electrical connection between the board and the electronic component.

19. The system of claim 13 further comprising four support bracket connectors configured to provide solder ball joint relief for the at least one electrical connection between the board and the electronic component.

20. The system of claim 13 further comprising a spring configured to apply tension to the heat sink connector.
